(19) United States
(12) Patent Application Publication
(10) Pub. No.: US 2021/0223295 A1
(43) Pub. Date: Jul. 22, 2021

(54) METHOD AND SYSTEM FOR DETECTING HARMONIC CURRENT IN SYNCHRONOUS MOTORS

(71) Applicants: TONGJI UNIVERSITY, Shanghai (CN); CRRC QINGDAO SIFANG CO., LTD., Qingdao (CN)

(72) Inventors: Jinsong KANG, Shanghai (CN); Siyuan MU, Shanghai (CN); Fujie JIANG, Qingdao (CN); Zhiqiang ZHANG, Qingdao (CN); Yanxiao LEI, Qingdao (CN)

(21) Appl. No.: 17/111,461

(22) Filed: Dec. 3, 2020

(30) Foreign Application Priority Data
Jan. 20, 2020 (CN) 202010065837.X

(51) Int. Cl. G01R 19/00; G01R 31/34

(52) U.S. Cl. CPC G01R 19/0092; G01R 31/343

(57) ABSTRACT

The present invention relates to a method and a system for detecting the harmonic current in synchronous motors. The method includes the following steps: (1) extracting the total stator current harmonics based on the control error between the reference value of fundamental stator current and the feedback value of stator current in the d, q coordinate; (2) using a plurality of synchronous coordinate transformations and low-pass filters to extract each harmonic to be detected from the total harmonic current. Compared with the prior art, firstly, the present invention extracts the total stator current harmonic and then uses a plurality of synchronous coordinate transformations to extract each harmonic to be detected from the total harmonic current, thus the interference of the high-amplitude fundamental component on the harmonic current detection can be suppressed; Secondly, the present invention uses the stator current control error in fundamental d, q coordinate to extract the total stator current harmonics based on the stator current sampling feedback value and the fundamental current reference value. The method is of high accuracy of harmonic current extraction, fast response speed and simple implementation.

### TECHNICAL FIELD

The present invention relates to the technical field of synchronous motor control, and in particular to a method and system for detecting the harmonic current in synchronous motor.

### BACKGROUND

PMSMs (Permanent magnet synchronous motors) are widely used as the drive motors with its high efficiency and high power density in the electric vehicles or the like. However, the back-EMF harmonic caused by the dead-time effect of the inverter, and the cogging and saturation effects of the motor causes the existence of harmonic current in stator windings that is of integer times of the fundamental frequency. If it is not controlled, the harmonic current will produce additional loss and torque ripple, which will affect motor efficiency and torque output stability.

Vector control is widely adopted in the traditional permanent magnet synchronous motor control, which uses PI (proportional integral) controllers to control the stator current in the d, q rotation coordinate. Due to the limitation of the bandwidth of the PI controller, it is difficult to control the harmonic current effectively, especially in the high-speed operation. Therefore, a harmonic current controller is needed beside the fundamental current controller.

In the current research, the multi-reference coordinate system method is applied to the detection and control of the harmonic current of the PMSM because of its clear principle and strong flexibility. For example, LIAO Y et. al., Suppress permanent magnet synchronous motor torque ripple with harmonic injection Proceedings of The Chinese Society for Electrical Engineering. 2011, Volume 31 (Issue 21), Pages 119-127. YAN L, LIAO Y, LIN H, et al. 2019. Torque ripple suppression of permanent magnet synchronous machines by minimal harmonic current injection. let Power Electronics [J], 12: 1368-1375. Harmonic current of any frequency can be independently detected and controlled in a reference coordinate rotating at the same speed. The traditional multiple reference coordinate based harmonic current detection method firstly performs a coordinate transformation on the three-phase stator current, and then extracts the stator current harmonic of the desired frequency through a low-pass filter. Afterwards, the current harmonic can be controlled.

However, in the prior art, the detection performance deteriorates in the permanent magnet synchronous motor for the electric vehicle and some high-power applications where the magnitude of the fundamental current is much higher than the harmonic's, due to the interference of the fundamental. And the detection result contains ripples, which affects the control performance of the harmonic current. Reducing the cut-off frequency of the low-pass filter or introducing an additional pre-filter can suppress DC interference, but it will slow down the response speed of harmonic current detection and also affect the control performance.

### SUMMARY

The purpose of the present invention is to provide a method and system for detecting the harmonic current in synchronous motor in order to overcome the above-mentioned defects in the prior art.

The purpose of the disclosure may be realized by the following technical solutions.

A method for detecting the harmonic current in synchronous motors is provided, the method comprising the following steps:

(1) extracting the total stator current harmonics based on the control error between the reference value of fundamental stator current and the feedback value of stator current in the d, q coordinate;

(2) using a plurality of synchronous coordinate transformations and low-pass filters to extract each harmonic to be detected from the total harmonic current.

The step (1) specifically comprises:

(11) obtaining the stator fundamental current reference value and the corresponding fundamental current feedback value in the d, q coordinate;

(12) estimating a stator actual fundamental current response in the d, q coordinate based on the stator fundamental current reference value in the d, q coordinate and a system current closed-loop transfer function;

(13) making a difference between the stator fundamental current feedback value and the estimated stator actual fundamental current response in the d, q coordinate to obtain the total stator current harmonics;

specifically:

i_{dqh}=i_{dq}−î_{dq0}=i_{dq}−i_{dqref}□H(s)

wherein, i_{dph} is the total stator current harmonics in the d, q coordinate, i_{dq} is the fundamental current feedback value in the d, q coordinate, i_{dq} is obtained by transforming a measured three-phase stator current through the d, q rotation coordinate transformation, î_{dq0} is the stator actual fundamental current response in the d, q coordinate, i_{dref} is the stator fundamental current reference value in the d, q coordinate, H(s) is the system current closed-loop transfer function, and S is a Laplace operator.

The step (2) specifically comprises:

(21) for a harmonic of a frequency to be detected, performing a synchronous coordinate transformation respectively to convert the harmonic current of the frequency to be detected into a direct current;

(22) passing the converted direct current through a low-pass filter, which can filter out the harmonic component, to obtain the current amplitude of the harmonic of the frequency to be detected.

In step (21), for a (6k±1)^{th} harmonic in stationary coordinate, a transformation matrix of the synchronous coordinate transformation is:

$${T}_{dq - dq ( 6 k - 1 )} = [ \begin{matrix}cos ( - 6 k {θ}_{e} ) & sin ( - 6 k {θ}_{e} ) \\ - sin ( - 6 k {θ}_{e} ) & cos ( - 6 k {θ}_{e} )\end{matrix} ] , {T}_{dq - dq ( 6 k + 1 )} = [ \begin{matrix}cos ( 6 k {θ}_{e} ) & sin ( 6 k {θ}_{e} ) \\ - sin ( 6 k {θ}_{e} ) & cos ( 6 k {θ}_{e} )\end{matrix} ] ,$$

wherein, T_{dq-dq(6k-1)} is a synchronous coordinate transformation matrix of the (6k−1)^{th} harmonic, T_{dq-dq(6k+1)} is a synchronous coordinate transformation matrix of the (6k+1)^{th} harmonic, θₑ is an electrical angle of the motor, and k=1, 2, . . . , n, n being a positive integer.

A system for detecting the harmonic current in synchronous motors is provided, the system comprising:

a total stator current harmonics extraction module configured to extract the total stator current harmonics based on the control error between the reference value of fundamental stator current and the feedback value of stator current in a d, q coordinate;

a plurality of harmonic current extraction modules configured to use multiple synchronous coordinate transformations and low-pass filters to extract each harmonic to be detected from the total harmonic current.

The total stator current harmonics extraction module comprises:

a current acquisition sub-module configured to obtain a stator fundamental current reference value i_{dqref} and a corresponding fundamental current feedback value i_{dq} in the d, q coordinate;

a fundamental current estimation sub-module configured to estimate a stator actual fundamental current response î_{dq0} in the d, q coordinate based on the stator fundamental current reference value i_{dqref} in the d, q coordinate and a system current closed-loop transfer function H(s): î_{dq0}=i_{dqref}□H(s), wherein S is a Laplace operator;

a subtractor configured to make a difference between the stator fundamental current feedback value i_{dq} and the estimated stator actual fundamental current response î_{dq0} in the d, q coordinate to obtain the total stator current harmonics i_{dqh}: i_{dqh}=i_{dq}−î_{dq0}=i_{dq}−i_{dqref}□H(s).

The plurality of harmonic current extraction modules comprise:

a plurality of synchronous coordinate transformation sub-modules configured to perform the synchronous coordinate transformations for a harmonic of a frequency to be detected respectively to convert a harmonic current of the frequency to be detected into a direct current;

a plurality of low-pass filters cascaded to the outputs of the plurality of synchronous coordinate transformation sub-modules respectively, and configured to pass the converted direct current through the low-pass filters, which can filter out the harmonic component in fundamental wave, to obtain the current amplitude of the harmonic of the frequency to be detected.

A transformation matrix of the synchronous coordinate transformation of the synchronous coordinate transformation sub-module is:

$${T}_{dq - dq ( 6 k - 1 )} = [ \begin{matrix}cos ( - 6 k {θ}_{e} ) & sin ( - 6 k {θ}_{e} ) \\ - sin ( - 6 k {θ}_{e} ) & cos ( - 6 k {θ}_{e} )\end{matrix} ] , {T}_{dq - dq ( 6 k + 1 )} = [ \begin{matrix}cos ( 6 k {θ}_{e} ) & sin ( 6 k {θ}_{e} ) \\ - sin ( 6 k {θ}_{e} ) & cos ( 6 k {θ}_{e} )\end{matrix} ] ,$$

wherein, T_{dq-dq(6k-1)} is a synchronous coordinate transformation matrix of the (6k−1)^{th} harmonic, T_{dq-dq(6k+1)} is a synchronous coordinate transformation matrix of the (6k+1)^{th} harmonic, and θₑ is an electrical angle of the motor, k=1, 2, . . . , n, n being a positive integer.

Compared with the prior art, the present invention has the following advantages:

(1) The present invention firstly extracts the total stator current harmonics, and then performs multi-synchronous coordinate transformation to extract each harmonic, which can suppress the interference of the high-amplitude fundamental component on the harmonic current detection;

(2) The present invention uses the stator current control error in fundamental d, q coordinate to extract the total stator current harmonics based on the stator current sampling feedback value and the fundamental current reference value, and the method is of high accuracy of harmonic current extraction, fast response speed and simple implementation.

### BRIEF DESCRIPTION OF DRAWINGS

FIG. 1 is a schematic block diagram of the method for detecting the harmonic current in synchronous motors of the present invention;

FIG. 2 is a schematic block diagram of the total stator current harmonics extraction of the present invention;

FIG. 3 is a comparison diagram of the harmonic current detection results between the method of the present invention and the prior art method, wherein FIG. 3 (a) is a comparison diagram for the 5^{th} harmonic current d-axis component, and FIG. 3 (b) is a comparison diagram for the 5^{th} harmonic current q-axis component, FIG. 3 (c) is a comparison diagram for the 7^{th} harmonic current d-axis component, and FIG. 3 (d) is a comparison diagram for the 7^{th} harmonic current q-axis component.

### DETAIL DESCRIPTION OF EMBODIMENTS

The present invention will be described in detail below with reference to the drawings and specific embodiments. Note that the description of the following embodiment is merely an example in nature, and the present invention is not intended to limit its application or its use, and the present invention is not limited to the following embodiments.

### EMBODIMENTS

As shown in FIG. 1, a method for detecting the harmonic current in synchronous motors is provided, the method comprising the following steps:

(1) extracting the total stator current harmonics based on the control error between the reference value of fundamental stator current and the feedback value of stator current in the d, q coordinate;

(2) using a plurality of synchronous coordinate transformations and low-pass filters to extract each harmonic to be detected from the total harmonic current.

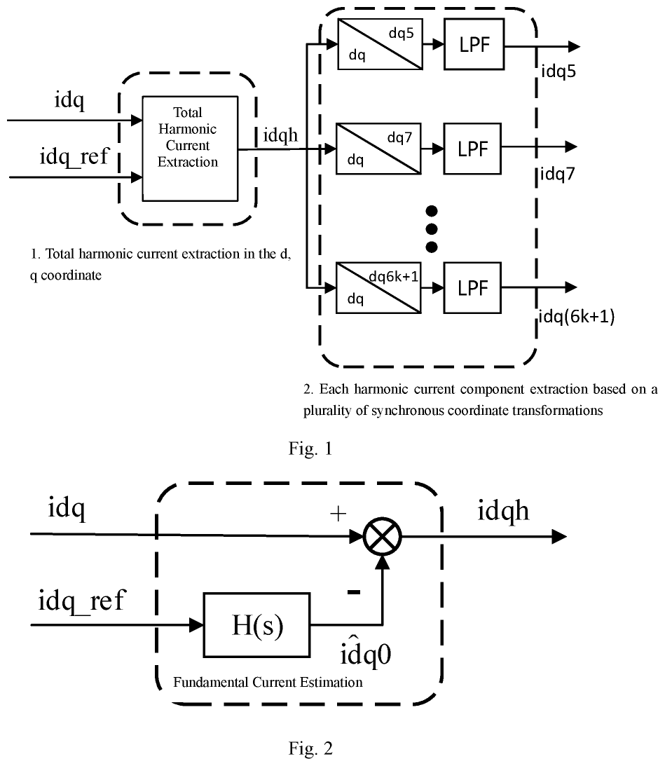

As shown in FIG. 2, the step (1) specifically comprises:

(11) obtaining the stator fundamental current reference value and the corresponding fundamental current feedback value in the d, q coordinate;

(12) estimating a stator actual fundamental current response in the d, q coordinate based on the stator fundamental current reference value in the d, q coordinate and a system current closed-loop transfer function;

(13) making a difference between the stator fundamental current feedback value and the estimated stator actual fundamental current response in the d, q coordinate to obtain the total stator current harmonics;

specifically:

i_{dqh}=i_{dq}−î_{dq0}=i_{dq}−i_{dqref}□H(s)

wherein, i_{dqh} is the total stator current harmonics in the d, q coordinate, i_{dq} is the fundamental current feedback value in the d, q coordinate, i_{dq} is obtained by transforming a measured three-phase stator current through the d, q rotation coordinate transformation, î_{dq0} is the stator actual fundamental current response in the d, q coordinate, i_{dqref} is the stator fundamental current reference value in the d, q coordinate, H(s) is the system current closed-loop transfer function, and S is a Laplace operator.

The step (2) specifically comprises:

(21) for a harmonic of a frequency to be detected, performing a synchronous coordinate transformation respectively to convert the harmonic current of the frequency to be detected into a direct current;

(22) passing the converted direct current through a low-pass filter, which can filter out the harmonic component, to obtain the current amplitude of the harmonic of the frequency to be detected.

In step (21), for a (6k±1)^{th} harmonic in stationary coordinate, a transformation matrix of the synchronous coordinate transformation is:

$${T}_{dq - dq ( 6 k - 1 )} = [ \begin{matrix}cos ( - 6 k {θ}_{e} ) & sin ( - 6 k {θ}_{e} ) \\ - sin ( - 6 k {θ}_{e} ) & cos ( - 6 k {θ}_{e} )\end{matrix} ] , {T}_{dq - dq ( 6 k + 1 )} = [ \begin{matrix}cos ( 6 k {θ}_{e} ) & sin ( 6 k {θ}_{e} ) \\ - sin ( 6 k {θ}_{e} ) & cos ( 6 k {θ}_{e} )\end{matrix} ] ,$$

wherein, T_{dq-dq(6k-1)} is a synchronous coordinate transformation matrix of the (6k−1)^{th} harmonic, T_{dq-dq(6k+1)} is a synchronous coordinate transformation matrix of the (6k+1)^{th} harmonic, θₑ is an electrical angle of the motor, and k=1, 2, . . . , n, n being a positive integer.

That is, when performing the synchronous coordinate transformation to obtain the direct current of the harmonic current, it can be obtained by the following transformation:

i_{dq(6k-1)}=T_{dq-dq(6k-1)}i_{dqh},i_{dq(6k+1)}=T_{dq-dq(6k+1)}i_{dqh}

wherein, i_{dq(6k-1)} is the direct current of the (6k−1)^{th} harmonic, i_{dq(6k+1)} is the direct current of the (6k+1)^{th} harmonic.

A system for detecting the harmonic current in synchronous motors is provided, the system comprising:

a total stator current harmonics extraction module configured to extract a total stator current harmonics based on the control error between the reference value of fundamental stator current and the feedback value of stator current in a d, q coordinate;

a plurality of harmonic current extraction modules configured to use multiple synchronous coordinate transformations and low-pass filters to extract each harmonic to be detected from the total harmonic current.

The total stator current harmonics extraction module comprises:

a current acquisition sub-module configured to obtain a stator fundamental current reference value i_{dqref} and a corresponding fundamental current feedback value i_{dq} in the d, q coordinate;

a fundamental current estimation sub-module configured to estimate a stator actual fundamental current response i_{dq0} in the d, q coordinate based on the stator fundamental current reference value i_{dqref} in the d, q coordinate and a system current closed-loop transfer function H(s): i_{dq0}=i_{dqref}□H(s), wherein S is a Laplace operator;

a subtractor configured to make a difference between the stator fundamental current feedback value i_{dq} and the estimated stator actual fundamental current response i_{dq0} in the d, q coordinate to obtain the total stator current harmonic i_{dqh}: i_{dqh}=i_{dq}−î_{dq0}=i_{dq}−i_{dqref}□H(s).

The plurality of harmonic current extraction modules comprises:

a plurality of synchronous coordinate transformation sub-modules configured to perform the synchronous coordinate transformations for a harmonic of a frequency to be detected respectively to convert a harmonic current of the frequency to be detected into a direct current;

a plurality of low-pass filters cascaded to the outputs of the plurality of synchronous coordinate transformation sub-modules respectively, and configured to pass the converted direct current through the low-pass filters, which can filter out the harmonic component in fundamental wave, to obtain the current amplitude of the harmonic of the frequency to be detected.

A transformation matrix of the synchronous coordinate transformation of the synchronous coordinate transformation sub-module is:

$${T}_{dq - dq ( 6 k - 1 )} = [ \begin{matrix}cos ( - 6 k {θ}_{e} ) & sin ( - 6 k {θ}_{e} ) \\ - sin ( - 6 k {θ}_{e} ) & cos ( - 6 k {θ}_{e} )\end{matrix} ] , {T}_{dq - dq ( 6 k + 1 )} = [ \begin{matrix}cos ( 6 k {θ}_{e} ) & sin ( 6 k {θ}_{e} ) \\ - sin ( 6 k {θ}_{e} ) & cos ( 6 k {θ}_{e} )\end{matrix} ] ,$$

wherein, T_{dq-dq(6k-1)} is a synchronous coordinate transformation matrix of the (6k−1)^{th} harmonic, T_{dq-dq(6k+1)} is a synchronous coordinate transformation matrix of the (6k+1)^{th} harmonic, and θₑ is an electrical angle of the motor, k=1, 2, . . . , n, n being a positive integer.

This embodiment is based on a permanent magnet synchronous motor drive system with a rated current of 230 A and a rated speed of 3000 rpm to verify the effectiveness of the harmonic current detection algorithm proposed in the present invention. The switching frequency of the inverter is 10 kHz, and its dead time is set to 5 microseconds.

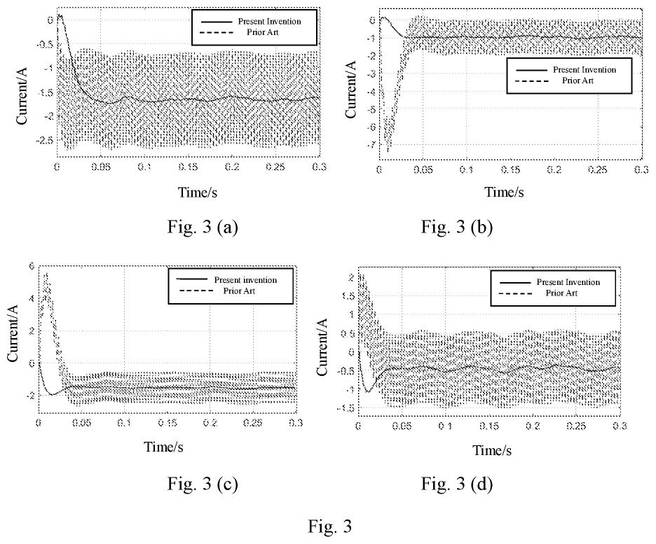

Taking the 5^{th} and 7^{th} harmonic currents as the examples, the existing harmonic current detection technology based on multi-synchronous coordinate transformation directly performs coordinate transformation on the stator current, and uses a low-pass filter to extract the harmonics, while the present invention firstly extracts the total stator current harmonics. Then it performs the coordinate transformation to the total stator current harmonics, and use the low-pass filters to extract the corresponding frequency and order harmonic afterward. When the parameters of the low-pass filters are the same, the comparison of the harmonic currents detected by the prior art and the method of the present invention is shown in FIG. 3. The solid line is the harmonic current detection result after the implementation of the present invention, and the dashed line is the harmonic current detection result in the prior art. It can be seen from the figure that due to the interference of the fundamental current under the rated current, the 5^{th} and 7^{th} harmonic currents detected by the existing harmonic current detection technology have great fluctuations. The harmonic current detection method provided by the present invention can overcome the interference of the fundamental, and extract the harmonic current amplitude quickly and effectively.

The above embodiments are only examples, and do not limit the scope of the present invention. These embodiments can also be implemented in other various ways, and various omissions, substitutions, and changes can be made without departing from the scope of the technical idea of the present invention.

1. A method for detecting the harmonic current in synchronous motors, the method comprising the following steps:
(1) extracting the total stator current harmonics based on the control error between the reference value of fundamental stator current and the feedback value of stator current in the d, q coordinate;
(2) using a plurality of synchronous coordinate transformations and low-pass filters to extract each harmonic to be detected from the total harmonic current.

2. The method for detecting the harmonic current in synchronous motors according to claim 1, wherein the step (1) specifically comprises:
(11) obtaining the stator fundamental current reference value and the corresponding fundamental current feedback value in the d, q coordinate;
(12) estimating a stator actual fundamental current response in the d, q coordinate based on the stator fundamental current reference value in the d, q coordinate and a system current closed-loop transfer function;
(13) making a difference between the stator fundamental current feedback value and the estimated stator actual fundamental current response in the d, q coordinate to obtain the total stator current harmonics;
specifically:
i_{dqh}=i_{dq}−î_{dq0}=i_{dq}−i_{dqref}□H(s)
wherein, i_{dqh} is the total stator current harmonics in the d, q coordinate, i_{dq} is the fundamental current feedback value in the d, q coordinate, i_{dq} is obtained by transforming a measured three-phase stator current through the d, q rotation coordinate transformation, i_{dq0} is the stator actual fundamental current response in the d, q coordinate, i_{dqref} is the stator fundamental current reference value in the d, q coordinate, H(s) is the system current closed-loop transfer function, and S is a Laplace operator.

3. The method for detecting the harmonic current in synchronous motors according to claim 1, wherein the step (2) specifically comprises:
(21) for a harmonic of a frequency to be detected, performing a synchronous coordinate transformation respectively to convert the harmonic current of the frequency to be detected into a direct current;
(22) passing the converted direct current through a low-pass filter, which can filter out the harmonic component, to obtain the current amplitude of the harmonic of the frequency to be detected.

4. The method for detecting the harmonic current in synchronous motors according to claim 3, wherein in step (21), for a (6k±1)^{th} harmonic in stationary coordinate, a transformation matrix of the synchronous coordinate transformation is:
$${T}_{dq - dq ( 6 k - 1 )} = [ \begin{matrix}cos ( - 6 k {θ}_{e} ) & sin ( - 6 k {θ}_{e} ) \\ - sin ( - 6 k {θ}_{e} ) & cos ( - 6 k {θ}_{e} )\end{matrix} ] , {T}_{dq - dq ( 6 k + 1 )} = [ \begin{matrix}cos ( 6 k {θ}_{e} ) & sin ( 6 k {θ}_{e} ) \\ - sin ( 6 k {θ}_{e} ) & cos ( 6 k {θ}_{e} )\end{matrix} ] ,$$
wherein, T_{dq-dq(6k-1)} is a synchronous coordinate transformation matrix of the (6k−1)^{th} harmonic, T_{dq-dq(6k-1)} is a synchronous coordinate transformation matrix of the (6k+1)^{th} harmonic, θₑ is an electrical angle of the motor, and k=1, 2, . . . , n, n being a positive integer.

5. A system for detecting the harmonic current in synchronous motors, the system comprising:
a total stator current harmonics extraction module configured to extract a total stator current harmonics based on the control error between the reference value of fundamental stator current and the feedback value of stator current in the d, q coordinate;
a plurality of harmonic current extraction modules configured to use multiple synchronous coordinate transformations and low-pass filters to extract each harmonic to be detected from the total harmonic current.

6. The system for detecting the harmonic current in synchronous motors according to claim 5, wherein the total stator current harmonics extraction module comprises:
a current acquisition sub-module configured to obtain a stator fundamental current reference value i_{dqref} and a corresponding fundamental current feedback value i_{dq} in the d, q coordinate;
a fundamental current estimation sub-module configured to estimate a stator actual fundamental current response î_{dq0} in the d, q coordinate based on the stator fundamental current reference value i_{dqref} in the d, q coordinate and a system current closed-loop transfer function H(s): î_{dq0}=i_{dqref}□H(s), wherein S is a Laplace operator;
a subtractor configured to make a difference between the stator fundamental current feedback value i_{dq} and the estimated stator actual fundamental current response î_{dq0} in the d, q coordinate to obtain the total stator current harmonics i_{dqh}: i_{dqh}=i_{dq}−î_{dq0}=i_{dq}−i_{dqref}□H(s).

7. The system for detecting the harmonic current in synchronous motors according to claim 5, wherein the plurality of harmonic current extraction modules comprise:
a plurality of synchronous coordinate transformation sub-modules configured to perform the synchronous coordinate transformations for a harmonic of a frequency to be detected respectively to convert a harmonic current of the frequency to be detected into a direct current;
a plurality of low-pass filters cascaded to the outputs of the plurality of synchronous coordinate transformation sub-modules respectively, and configured to pass the converted direct current through the low-pass filters, which can filter out the harmonic component in fundamental wave, to obtain the current amplitude of the harmonic of the frequency to be detected.

8. The system for detecting the harmonic current in synchronous motors according to claim 7, wherein a transformation matrix of the synchronous coordinate transformation of the synchronous coordinate transformation sub-module is:
$${T}_{dq - dq ( 6 k - 1 )} = [ \begin{matrix}cos ( - 6 k {θ}_{e} ) & sin ( - 6 k {θ}_{e} ) \\ - sin ( - 6 k {θ}_{e} ) & cos ( - 6 k {θ}_{e} )\end{matrix} ] , {T}_{dq - dq ( 6 k + 1 )} = [ \begin{matrix}cos ( 6 k {θ}_{e} ) & sin ( 6 k {θ}_{e} ) \\ - sin ( 6 k {θ}_{e} ) & cos ( 6 k {θ}_{e} )\end{matrix} ] ,$$
wherein, T_{dq-dq(6k-1)} is a synchronous coordinate transformation matrix of the (6k−1)^{th} harmonic, T_{dq-dq(6k+1)} is a synchronous coordinate transformation matrix of the (6k+1)^{th} harmonic, and θₑ is an electrical angle of the motor, k=1, 2, . . . , n, n being a positive integer.
